(19) United States
(12) Patent Application Publication
(10) Pub. No.: US 2019/0252351 A1
(43) Pub. Date: Aug. 15, 2019

(54) SEMICONDUCTOR PACKAGE STRUCTURE HAVING AN ANTENNA PATTERN ELECTRICALLY COUPLED TO A FIRST REDISTRIBUTION LAYER (RDL)

(71) Applicant: MediaTek Inc., Hsin-Chu (TW)

(72) Inventors: Tzu-Hung Lin, Hsin-Chu (TW); I-Hsuan Peng, Hsinchu City (TW); Nai-Wei Liu, Hsin-Chu (TW); Ching-Wen Hsiao, Hsinchu City (TW); Wei-Che Huang, Zhudong Township (TW)

(73) Assignee: MediaTek Inc., Hsin-Chu (TW)

(21) Appl. No.: 16/279,925

(22) Filed: Feb. 19, 2019

Related U.S. Application Data
(62) Division of application No. 15/130,994, filed on Apr. 17, 2016, now abandoned.
(60) Provisional application No. 62/256,218, filed on Nov. 17, 2015.
(60) Provisional application No. 62/157,046, filed on May 5, 2015.

(51) Int. Cl. H01L 25/065; H01L 23/66; H01L 23/00; H01L 25/16; H01L 23/552; H01L 23/31; H01L 23/538; H01L 23/522

(52) U.S. Cl. CPC H01L 25/0652; H01L 2924/19043; H01L 24/19; H01L 24/20; H01L 25/16; H01L 23/552; H01L 23/3171; H01L 23/3128; H01L 23/5385; H01L 23/5389; H01L 23/5226; H01L 2224/12105; H01L 2224/04105; H01L 2224/04042; H01L 2223/6677; H01L 2924/1207; H01L 2924/1205; H01L 2924/1206; H01L 2224/02331; H01L 2224/32225; H01L 2224/73267; H01L 2924/1421; H01L 2924/1435; H01L 2924/1438; H01L 2924/19011; H01L 2924/19041; H01L 2924/19042; H01L 2224/02379; H01L 2924/3025; H01L 23/66

(57) ABSTRACT

A semiconductor package structure including a first semiconductor package is provided. The first semiconductor package includes a first semiconductor package including a first redistribution layer (RDL) structure having a first surface and a second surface opposite thereto. A first semiconductor die and a first molding compound that surrounds the first semiconductor die are disposed on the first surface of the first RDL structure. An IMD structure having a conductive layer with an antenna pattern or a conductive shielding layer is disposed on the first molding compound and the first semiconductor die.

### CROSS REFERENCE TO RELATED APPLICATIONS

This application claims the benefit of U.S. Provisional Application No. 62/157,046 filed on May 5, 2015 and U.S. Provisional Application No. 62/256,218 filed on Nov. 17, 2015, the entirety of which is incorporated by reference herein.

### BACKGROUND OF THE INVENTION

### Field of the Invention

The present invention relates to a semiconductor package structure, and in particular to a fan-out package structure including an integrated antenna.

### Description of the Related Art

In order to ensure the continued miniaturization and multi-functionality of electronic products and communication devices, it is desired that semiconductor packages be small in size, support multi-pin connection, operate at high speeds, and have high functionality. Additionally, in a high frequency application, such as a radio frequency (RF) system-in-package (SiP) assembly, antennas are typically used for enabling wireless communication.

In such a conventional SiP structure, a discrete antenna component is individually encapsulated or mounted on a printed circuit board (PCB) or package. However, the PCB is required to provide additional area for the antenna component mounted thereon. As a result, it is difficult to reduce the device size. Additionally, the total height of the SiP structure is increased when the antenna component is mounted on the package. Moreover, in this case, since the antenna component is typically mounted on the package by a surface mount technology (SMT) process, poor SMT process control may induce delamination between the antenna component and the underlying package. As a result, reliability, yield, and throughput of the semiconductor package structure are reduced.

Thus, a novel semiconductor package structure is desirable.

### BRIEF SUMMARY OF THE INVENTION

Semiconductor package structures are provided. An exemplary embodiment of a semiconductor package structure includes a first semiconductor package. The first semiconductor package includes a first RDL structure having a first surface and a second surface opposite thereto. The first semiconductor package further includes a first semiconductor die disposed on the first surface of the first RDL structure. The first semiconductor package further includes a first molding compound disposed on the first surface of the first RDL structure and surrounding the first semiconductor die. The first semiconductor package further includes an inter-metal dielectric (IMD) structure disposed on the first molding compound and the first semiconductor die. The IMD structure has a conductive layer with an antenna pattern that is electrically coupled to the first RDL structure.

Another exemplary embodiment of a semiconductor package structure includes a first semiconductor package. The first semiconductor package includes a first RDL structure having a first surface and a second surface opposite thereto. The first semiconductor package further includes a first semiconductor die disposed on the first surface of the first RDL structure. The first semiconductor package further includes a first molding compound disposed on the first surface of the first RDL structure and surrounding the first semiconductor die. The first semiconductor package further includes an IMD structure disposed on the first molding compound and the first semiconductor die. The IMD structure has a conductive shielding layer that covers the first semiconductor die.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A is a cross-sectional view of an exemplary semiconductor package structure in accordance with some embodiments of the disclosure.

FIG. 1B is a plan view of an IMD structure of the semiconductor package structure shown in FIG. 1A.

FIG. 2 is a cross-sectional view of an exemplary semiconductor package structure with two semiconductor dies arranged side-by-side in accordance with some embodiments of the disclosure.

FIG. 3 is a cross-sectional view of an exemplary semiconductor package structure with a package on package (PoP) structure in accordance with some embodiments of the disclosure.

FIG. 4A is a cross-sectional view of an exemplary semiconductor package structure in accordance with some embodiments of the disclosure.

FIG. 4B is a plan view of an IMD structure of the semiconductor package structure shown in FIG. 4A.

FIG. 5 is a cross-sectional view of an exemplary semiconductor package structure with two semiconductor dies arranged side-by-side in accordance with some embodiments of the disclosure.

FIG. 6 is a cross-sectional view of an exemplary semiconductor package structure with a package on package (PoP) structure in accordance with some embodiments of the disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

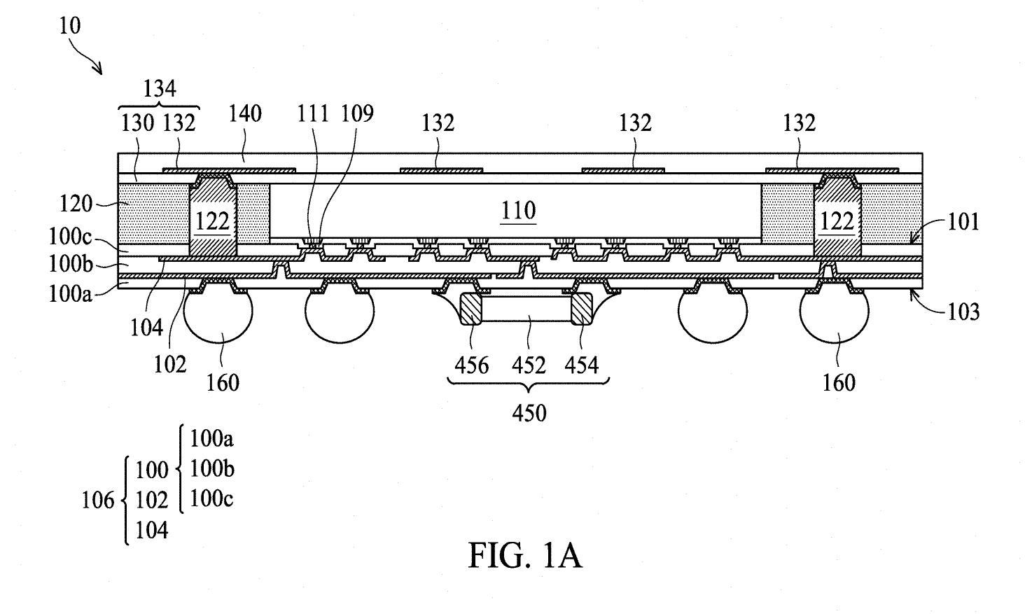

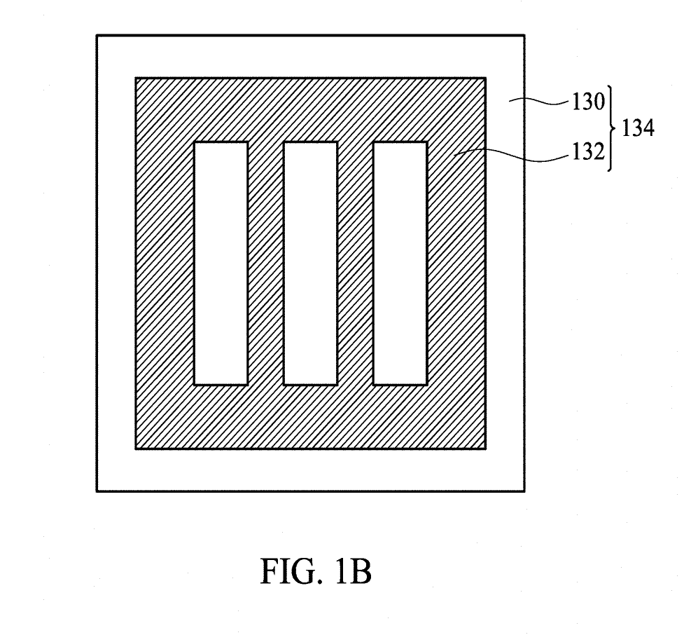

FIG. 1A is a cross-sectional view of a semiconductor package structure 10 in accordance with some embodiments of the disclosure. FIG. 1B is a plan view of an IMD structure 134 of the semiconductor package structure 10 shown in FIG. 1A. In some embodiments, the semiconductor package structure 10 is a wafer-level semiconductor package structure, for example, a flip-chip semiconductor package structure.

Referring to FIG. 1A, the semiconductor package structure 10 includes a first semiconductor package, such as a wafer-level semiconductor package, that may be mounted on a base (not shown). In some embodiments, the first semiconductor package may include a system-on-chip (SOC) package. Moreover, the base may include a printed circuit board (PCB) and may be formed of polypropylene (PP). In some embodiments, the base may include a package substrate. The first semiconductor package of the semiconductor package structure 10 is mounted on the base by a bonding process. For example, the first semiconductor package includes a plurality of first conductive structures 160 that is mounted on and electrically coupled to the base by the bonding process.

The first semiconductor package includes a first semiconductor die 110 and a first RDL structure 106. The first semiconductor die 110, for example, may include a microcontroller (MCU), a microprocessor (MPU), a random access memory (RAM), a power management integrated circuit (PMIC), a flash memory, a global positioning system (GPS) device, or a radio frequency (RF) device or any combination thereof. Moreover, for example, the first conductive structures 160 may comprise a conductive bump structure such as a copper bump or a solder bump structure, a conductive pillar structure, a conductive wire structure, or a conductive paste structure.

As shown in FIG. 1A, the first semiconductor die 110 is fabricated by flip-chip technology. Pads 109 of the first semiconductor die 110 are electrically connected to the circuitry (not shown) of the first semiconductor die 110. In some embodiments, the pads 109 belong to the uppermost metal layer of the interconnection structure (not shown) of the first semiconductor die 110. The pads 109 of the first semiconductor die 110 are in contact with the corresponding conductive structures 111, for example, conductive bumps, posts or solder pastes. It should be noted that the number of semiconductor dies integrated in the semiconductor package structure 10 is not limited to that disclosed in the embodiment.

The first RDL structure 106, which is also referred to as a fan-out structure, has a first surface 101 and a second surface 103 opposite thereto. The first semiconductor die 110 is disposed on the first surface 101 of the first RDL structure 106. The first semiconductor die 110 is connected to the first RDL structure 106 through the conductive structures 111.

In the embodiment, the first RDL structure 106 includes one or more conductive traces disposed in an inter-metal dielectric (IMD) layer 100. For example, a plurality of first conductive traces 104 is disposed at a first layer-level of the IMD layer 100 and at least one of the first conductive traces 104 is electrically coupled to the first semiconductor die 110. Moreover, a plurality of second conductive traces 102 is disposed at a second layer-level different from the first layer-level of the IMD layer 100. In this case, the IMD layer 100 may include first, second, and third sub-dielectric layers 100a, 100b, and 100c successively stacked from the second surface 103 of the first RDL structure 106 toward the first surface 101 of the first RDL structure 106, such that the first conductive traces 104 are positioned on the third sub-dielectric layer 100c and the second conductive traces 102 are positioned on the second sub-dielectric layer 100b and covered by the first sub-dielectric layer 100a. Also, the first conductive traces 104 are separated from the second conductive traces 102 by the second sub-dielectric layer 100b. In some embodiments, the IMD layer 100 may be formed of organic materials, which include a polymer base material, non-organic materials, which include silicon nitride (SiN_{X}), silicon oxide (SiO_{X}), graphene, or the like. For example, the first, second, third sub-dielectric layers 100a, 100b, and 100c are made of a polymer base material.

In some embodiments, the IMD layer 100 is a high-k dielectric layer (k is the dielectric constant of the dielectric layer). In some other embodiments, the IMD layer 100 may be formed of a photo sensitive material, which includes a dry film photoresist, or a taping film.

Pad portions of the second conductive traces 102 are exposed to openings of the first sub-dielectric layers 100a and connected to the first conductive structures 160 that are disposed on the second surface 103 of the first RDL structure 106. Also, it should be noted that the number of conductive traces and the number of sub-dielectric layers of the first RDL structure 106 shown in FIG. 1A is only an example and is not a limitation to the present invention.

In the embodiment, the first semiconductor package further includes at least one electronic component 450, such as an integrated passive device (IPD), disposed on the second surface 103 of the first RDL structure 106. The IPD is electrically coupled to the first semiconductor die 110 through the first RDL structure 106. In some embodiments, the IPD may include a capacitor, an inductor, a resistor, or a combination thereof. Moreover, the IPD includes at least one electrode electrically coupled to one of the second conductive traces 102. For example, the electronic component 450 may be a capacitor that is electrically coupled to the first semiconductor die 110. In this case, the capacitor includes a body 452 and first and second electrode layers 454 and 456 respectively disposed on two ends of the body 452. Moreover, the first and second electrode layers 454 and 456 are respectively electrically coupled to at least two of the second conductive traces 102.

In the embodiment, as shown in FIG. 1A, the first semiconductor package further includes a first molding compound 120 disposed on the first surface 101 of the first RDL structure 106 and surrounding the first semiconductor die 110. In some embodiments, the first molding compound 120 may be formed of an epoxy, a resin, a moldable polymer, or the like. The first molding compound 120 may be applied while substantially liquid, and then may be cured through a chemical reaction, such as in an epoxy or resin. In some other embodiments, the first molding compound 120 may be an ultraviolet (UV) or thermally cured polymer applied as a gel or malleable solid capable of being disposed around the first semiconductor die 110, and then may be cured through a UV or thermal curing process. The first molding compound 120 may be cured with a mold (not shown).

In the embodiment, the first molding compound 120 includes first vias 122 passing through it. The first vias 122 are electrically coupled to the first conductive traces 104 of the first RDL structure 106. Moreover, the first semiconductor die 110 may be surrounded by the first vias 122. In some embodiments, the first vias 122 may comprise through package vias (TPVs) formed of copper.

The first conductive structures 160 are separated from the first molding compound 120 through the first RDL structure 106. In other words, the first conductive structures 160 are free from contact with the first molding compound 120. In some embodiments, the first conductive structures 160 may comprise a conductive bump structure (such as a copper or solder bump structure), a conductive pillar structure, a conductive wire structure, or a conductive paste structure.

In the embodiment, as shown in FIG. 1A, the first semiconductor package further includes an IMD structure 134 disposed on the first molding compound 120 and the first semiconductor die 110. The methods and materials used for forming the IMD structure 134 may be the same as or similar to those of the first RDL structure 106. In other words, the process for forming the first RDL structure 106 can be used for forming the IMD structure 134. In the embodiment, the IMD structure 134 includes a conductive layer 132 with an antenna pattern disposed on a dielectric layer 130 and electrically coupled to the first RDL structure 106 through the first vias 122. In some embodiments, the conductive layer 132 with an antenna pattern may be embedded within the dielectric layer 130. The methods and materials used for forming the conductive layer 132 with an antenna pattern may be the same as or similar to those of the first conductive traces 104 and the second conductive traces 102. Moreover, the dielectric layer 130 may be a single layer or a multi-layer structure. Also, the methods and materials used for forming the dielectric layer 130 may be the same as or similar to those of the first, second, or third sub-dielectric layer 100a, 100b, or 100c.

In the embodiment, the antenna pattern of the conductive layer 132 is a fence pattern in a top view, as shown in FIG. 1B. However, it should be understood that those of ordinary skill in the art know that various shapes can be used for the antenna pattern of the conductive layer 132. The conductive layer 132 with an antenna pattern enables wireless communication for the semiconductor package structure 10.

In the embodiment, as shown in FIG. 1A, the first semiconductor package further includes an optional passivation layer 140 covering the IMD structure 134, so as to protect the conductive layer 132 with an antenna pattern from damage. The passivation layer 140 may be composed of a material that is the same as or different from that of the dielectric layer 130. For example, the passivation layer 140 may comprise an epoxy, a solder mask, an inorganic material (e.g., silicon nitride (SiNX), silicon oxide (SiOX), graphene, or the like), or an organic polymer base material. In cases where the conductive layer 132 with an antenna pattern is embedded within the dielectric layer 130, the passivation layer 140 may be omitted.

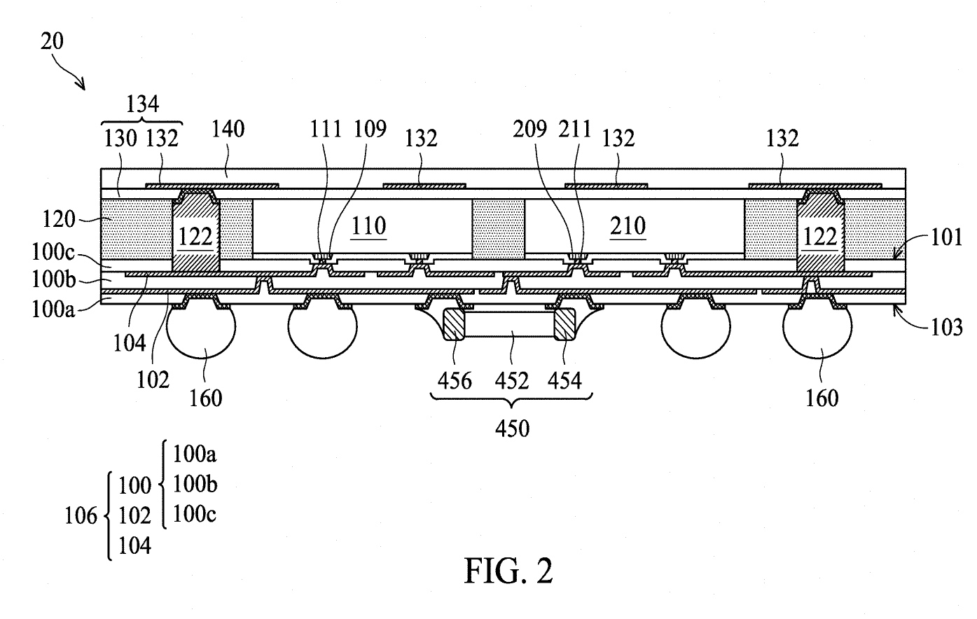

FIG. 2 is a cross-sectional view of an exemplary semiconductor package structure 20 with first and second semiconductor dies 110 and 210 arranged side-by-side in accordance with some embodiments of the disclosure. Descriptions of elements of the embodiments hereinafter that are the same as or similar to those previously described with reference to FIG. 1A are omitted for brevity. In the embodiment, the semiconductor package structure 20 is similar to the semiconductor package structure 10 shown in FIG. 1A, except that the first semiconductor package of the semiconductor package structure 20 further includes a second semiconductor die 210 disposed on the first surface 101 of the first RDL structure 106 and surrounded by the first molding compound 120 and the first vias 122. In the embodiment, the first and second semiconductor dies 110 and 210 are arranged side-by-side. Pads 209 of the second semiconductor die 210 are electrically connected to the circuitry (not shown) of the second semiconductor die 210. In some embodiments, the pads 209 belong to the uppermost metal layer of the interconnection structure (not shown) of the second semiconductor die 210. The pads 209 of the second semiconductor die 210 are in contact with the corresponding conductive structures 211, for example, conductive bumps, posts or solder pastes. The second semiconductor die 210 is electrically coupled to the first semiconductor die 110 through the pads 209, conductive structures 211, and the first RDL structure 106. It should be noted that the number of semiconductor dies integrated in the semiconductor package structure 20 is not limited to that disclosed in the embodiment.

In some embodiments, the second semiconductor die 210 may include an MCU), an MPU, a RAM, a PMIC, a flash memory, a GPS device, or an RF device or any combination thereof. In some embodiments, at least one of the first and second semiconductor dies 110 and 210 is a SOC die. For example, the first and second semiconductor dies 110 and 210 are SOC dies. Alternatively, the first semiconductor die 110 is a SOC die, and the second semiconductor die 210 is a memory die. Therefore, the first semiconductor package of the semiconductor package assembly 20 may include a pure SOC package or a hybrid SOC package. However, the number and the arrangement of semiconductor dies are not limited to the disclosed embodiment.

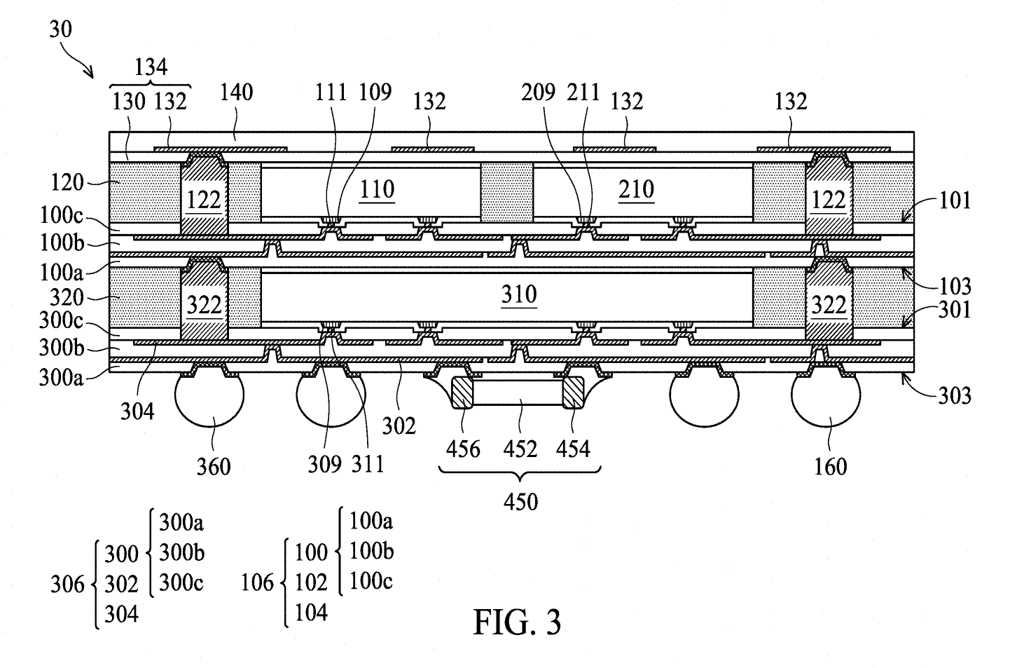

FIG. 3 is a cross-sectional view of an exemplary semiconductor package structure 30 with a package on package (PoP) structure in accordance with some embodiments of the disclosure. Descriptions of elements of the embodiments hereinafter that are the same as or similar to those previously described with reference to FIGS. 1A and 2 are omitted for brevity. In the embodiment, the semiconductor package structure 30 is similar to the semiconductor package structure 20 shown in FIG. 2, except that the semiconductor package structure 30 further includes a second semiconductor package stacked below the first semiconductor package of the semiconductor package structure 20. In some embodiments, the semiconductor package structure 30 is similar to the semiconductor package structure 10 shown in FIG. 1A, except that the semiconductor package structure 30 further includes a second semiconductor package stacked below the first semiconductor package of the semiconductor package structure 10.

In the embodiment, the second semiconductor package has a structure similar to that of the first semiconductor package of the semiconductor package structure 10 shown in FIG. 1A. The second semiconductor package, such as a wafer-level semiconductor package, that may be mounted on a base (not shown). In some embodiments, the second semiconductor package may include a SOC package. Moreover, the second semiconductor package of the semiconductor package structure 30 is mounted on the base via a plurality of second conductive structures 360 using a bonding process. The second conductive structures 360 may be the same as or similar to the first conductive structures 160.

The second semiconductor package includes a third semiconductor die 310 and a second RDL structure 306. The third semiconductor die 310, for example, may include an MCU, an MPU, a RAM, a PMIC, a flash memory, a GPS device, or a RF device or any combination thereof. Similarly, the third semiconductor die 310 is fabricated by flip-chip technology. Pads 309 of the third semiconductor die 310 are electrically connected to the circuitry (not shown) of the third semiconductor die 310. In some embodiments, the pads 309 belong to the uppermost metal layer of the interconnection structure (not shown) of the third semiconductor die 310. The pads 309 of the third semiconductor die 310 are in contact with the corresponding conductive structures 311, for example, conductive bumps, posts or solder pastes. It should be noted that the number of semiconductor dies integrated in the second semiconductor package is not limited to that disclosed in the embodiment.

The second RDL structure 306, which is also referred to as a fan-out structure, has a third surface 301 and a fourth surface 603 opposite thereto. The third semiconductor die 310 is disposed on the third surface 301 of the second RDL structure 306. The third semiconductor die 310 is connected to the second RDL structure 306 through the conductive structures 311.

In the embodiment, the second RDL structure 306 has a structure that is the same as or similar to that of the first RDL structure 106. For example, a plurality of first conductive traces 304 is disposed at a first layer-level of the IMD layer 300 and at least one of the first conductive traces 304 is electrically coupled to the third semiconductor die 310. Moreover, a plurality of second conductive traces 302 is disposed at a second layer-level different from the first layer-level of the IMD layer 300. In this case, the IMD layer 300 may include first, second, and third sub-dielectric layers 300a, 300b, and 300c successively stacked from the second surface 303 of the second RDL structure 306 toward the first surface 301 of the second RDL structure 306, such that the first conductive traces 304 are positioned on the third sub-dielectric layer 300c and the second conductive traces 302 are positioned on the second sub-dielectric layer 300b and covered by the first sub-dielectric layer 300a. Also, the first conductive traces 304 are separated from the second conductive traces 302 by the second sub-dielectric layer 300b. In some embodiments, the IMD layer 300 may be formed of a material that is the same as or similar to that of the IMD layer 100.

Pad portions of the second conductive traces 302 are exposed to openings of the first sub-dielectric layers 300a and connected to the second conductive structures 360 that are disposed on the second surface 303 of the second RDL structure 306. Also, it should be noted that the number of conductive traces and the number of sub-dielectric layers of the second RDL structure 306 shown in FIG. 3 is only an example and is not a limitation to the present invention.

In the embodiment, the second semiconductor package further includes an electronic component 450 that is disposed on the fourth surface 303 of the second RDL structure 306. The electronic component 450, such as a capacitor, includes a body 452 and first and second electrode layers 454 and 456 respectively disposed on two ends of the body 452 and respectively electrically coupled to at least two of the second conductive traces 302.

In the embodiment, as shown in FIG. 3, the second semiconductor package further includes a second molding compound 320 disposed on the first surface 301 of the second RDL structure 306 and surrounding the third semiconductor die 310. In some embodiments, the second molding compound 320 may be formed of a material that is the same as or similar to that of first molding compound 120.

In the embodiment, the second molding compound 320 includes second vias 322 passing through it. The second vias 322 are electrically coupled to the first conductive traces 304 of the second RDL structure 306, so as to form an electrical connection between the first and second RDL structures 106 and 306. Moreover, the third semiconductor die 310 may be surrounded by the second vias 322. In some embodiments, the second vias 322 may comprise TPVs formed of copper. Also, the second conductive structures 360 are separated from the second molding compound 320 through the second RDL structure 306.

According to the foregoing embodiments, the semiconductor package structure is designed to fabricate an antenna integrated into the first semiconductor package(s). The antenna provides wireless communication and a compatible process for the semiconductor package structure. Accordingly, there is no need to perform an SMT process for forming the antenna device. As a result, reliability, yield, and throughput of the semiconductor package structure are increased and the manufacturing cost of the semiconductor package structure is reduced. Additionally, the integrated antenna can provide design flexibility for the system integration of the semiconductor package structure.

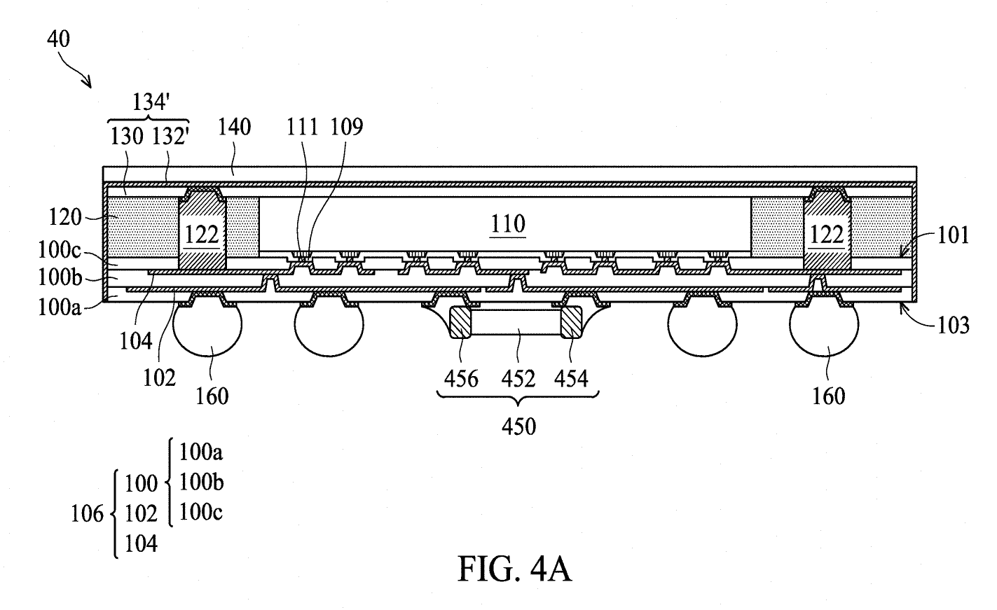

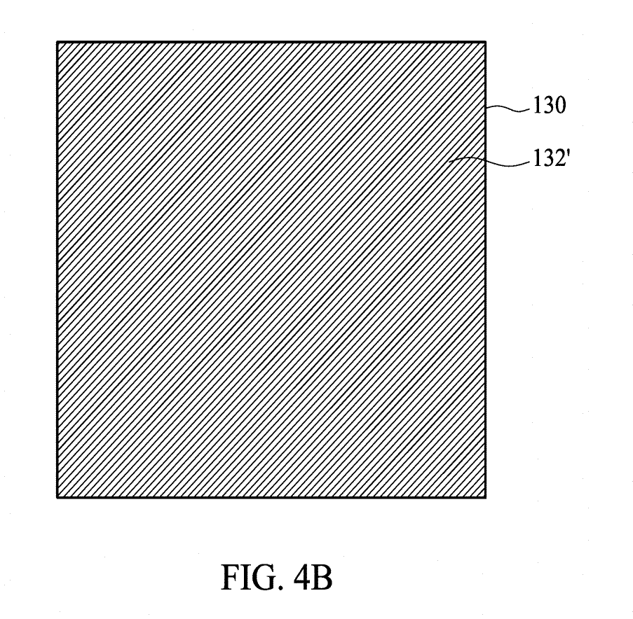

FIG. 4A is a cross-sectional view of a semiconductor package structure 40 in accordance with some embodiments of the disclosure. FIG. 4B is a plan view of an IMD structure 134′ of the semiconductor package structure 40 shown in FIG. 4A. Descriptions of elements of the embodiments hereinafter that are the same as or similar to those previously described with reference to FIGS. 1A and 1B are omitted for brevity. In the embodiment, the semiconductor package structure 40 is similar to the semiconductor package structure 10 shown in FIG. 1A, except that the IMD structure 134′ of the semiconductor package structure 40 has a conductive shielding layer 132′ that covers the first semiconductor die 110 and is uncovered by any passivation layer. As shown in FIG. 4B, unlike the conductive layer 132 with an antenna pattern shown in FIG. 1A, the conductive shielding layer 132′ is a solid/continuous layer without any pattern/opening therein. The conductive shielding layer 132′ is disposed on and substantially covers the entire upper surface of the dielectric layer 130. Moreover, the conductive shielding layer 132′ further extends along the sidewalls of the dielectric layer 130, the first molding compound 120, and the IMD layer 100 to the second surface 103 of the first RDL structure 106, so that the sidewall of the semiconductor package structure 40 is substantially covered by the conductive shielding layer 132′. In the embodiment, the conductive shielding layer 132′ is electrically coupled to at least one of the first vias 122. The conductive shielding layer 132′ is employed to reduce electrical noise from affecting the signals, and to reduce electromagnetic radiation that may interfere with other devices.

In the embodiment, the methods and materials used for forming the IMD structure 134′ are the same as or similar to those of the IMD structure 134 shown in FIG. 1A. In other words, the methods and materials used for forming the conductive shielding layer 132′ are the same as or similar to those of the conductive layer 132 with an antenna pattern shown in FIG. 1A.

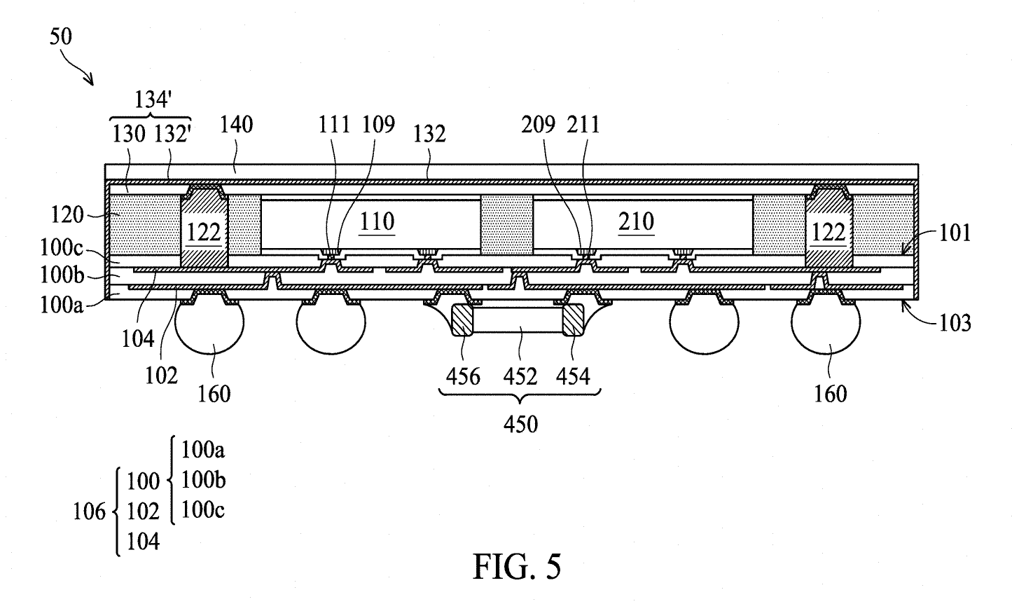

FIG. 5 is a cross-sectional view of an exemplary semiconductor package structure 50 with first and second semiconductor dies 110 and 210 arranged side-by-side in accordance with some embodiments of the disclosure. Descriptions of elements of the embodiments hereinafter that are the same as or similar to those previously described with reference to FIGS. 4A and 2 are omitted for brevity. In the embodiment, the semiconductor package structure 50 is similar to the semiconductor package structure 20 shown in FIG. 2, except that the IMD structure 134′ of semiconductor package structure 50 has a conductive shielding layer 132′ that covers the first and second semiconductor dies 110 and 210 and is uncovered by any passivation layer. Also, as shown in FIG. 5, the conductive shielding layer 132′ further extends along the sidewalls of the dielectric layer 130, the first molding compound 120, and the IMD layer 100 to the second surface 103 of the first RDL structure 106, so that the sidewall of the semiconductor package structure 50 is substantially covered by the conductive shielding layer 132′. In the embodiment, the conductive shielding layer 132′ is electrically coupled to at least one of the first vias 122 to reduce electrical noise from affecting the signals, and to reduce electromagnetic radiation that may interfere with other devices.

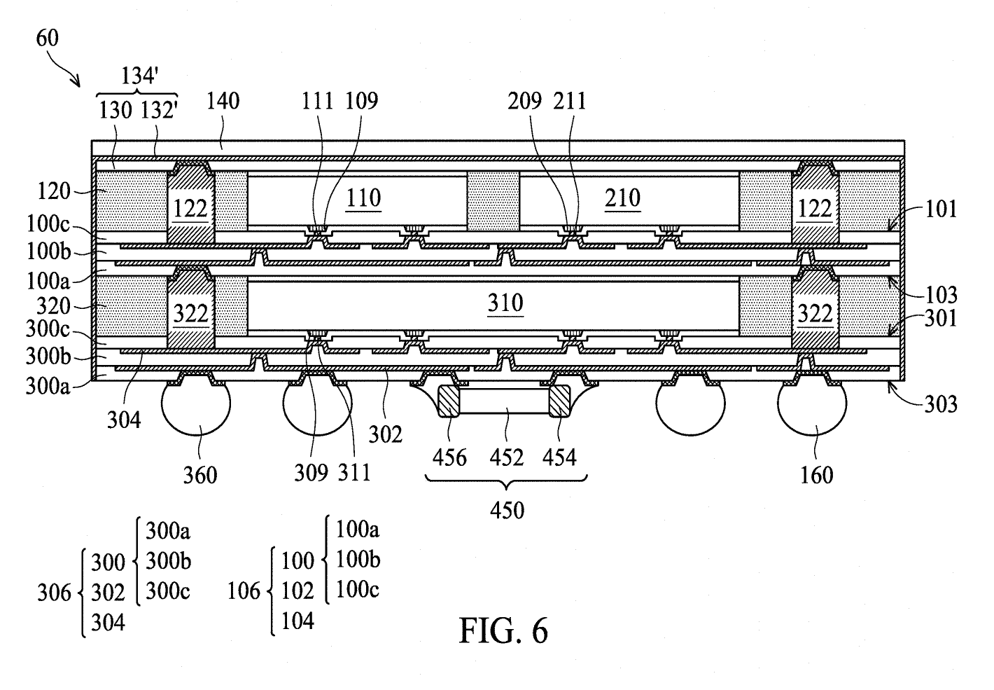

FIG. 6 is a cross-sectional view of an exemplary semiconductor package structure 60 with a PoP structure in accordance with some embodiments of the disclosure. Descriptions of elements of the embodiments hereinafter that are the same as or similar to those previously described with reference to FIGS. 4A and 3 are omitted for brevity. In the embodiment, the semiconductor package structure 60 is similar to the semiconductor package structure 30 shown in FIG. 3, except that the IMD structure 134′ of semiconductor package structure 60 has a conductive shielding layer 132′ that covers the first and second semiconductor dies 110 and 210 and is uncovered by any passivation layer. Similarly, as shown in FIG. 6, the conductive shielding layer 132′ further extends along the sidewalls of the dielectric layer 130, the first molding compound 120, the IMD layer 100, the second molding compound 320, and the IMD layer 300 to the second surface 103 of the second RDL structure 306, so that the sidewall of the semiconductor package structure 60 is substantially covered by the conductive shielding layer 132′. In the embodiment, the conductive shielding layer 132′ is electrically coupled to at least one of the first vias 122 to reduce electrical noise from affecting the signals, and to reduce electromagnetic radiation that may interfere with other devices.

According to the foregoing embodiments, the semiconductor package structure is designed to fabricate a shielding layer integrated into the semiconductor package(s). The shielding layer provides the function of reducing electrical noise and electromagnetic radiation and a compatible process for the semiconductor package structure. Accordingly, there is no need to perform an additional process for forming the shielding device. As a result, reliability, yield, and throughput of the semiconductor package structure are increased and the manufacturing cost of the semiconductor package structure is reduced. Additionally, the integrated shielding layer can provide design flexibility for the system integration of the semiconductor package structure.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1.-28. (canceled)

29. A semiconductor package structure comprising:
a redistribution layer (RDL) structure having a first surface and a second surface opposite to the first surface;
a semiconductor die disposed on the first surface of the RDL structure;
a molding compound disposed on the first surface of the RDL structure and surrounding the semiconductor die;
an inter-metal dielectric (IMD) structure disposed on the molding compound and the semiconductor die, wherein the IMD structure has a conductive layer electrically coupled to the RDL structure;
a plurality of conductive structures disposed on the second surface of the RDL structure and electrically coupled to the RDL structure; and
an electronic component disposed on the second surface of the RDL structure and electrically coupled to the RDL structure, wherein the conductive structures and the electronic component are disposed on an external mounting surface of the semiconductor package structure.

30. The semiconductor package structure as defined in claim 29, wherein the electronic component comprises a capacitor, an inductor, a resistor, or a combination thereof.

31. The semiconductor package structure as defined in claim 30, wherein the conductive structures comprise conductive bump structures.

32. The semiconductor package structure as defined in claim 29, wherein the conductive layer comprises an antenna pattern.

33. The semiconductor package structure as defined in claim 29, wherein the conductive layer comprises a conductive shielding layer.

34. The semiconductor package structure as defined in claim 29, further comprising a second semiconductor die disposed on the first surface of the RDL structure.

35. The semiconductor package structure as defined in claim 29, further comprising a plurality of vias coupled between the conductive layer and the RDL structure.

36. The semiconductor package structure as defined in claim 29, further comprising a passivation layer convering the IMD structure.

37. A semiconductor package structure comprising:
a first semiconductor package, comprising:
a first RDL structure having a first surface and a second surface opposite to the first surface;
a first semiconductor die disposed on the first surface of the first RDL structure;
a first molding compound disposed on the first surface of the first RDL structure and surrounding the first semiconductor die; and
an IMD structure disposed on the first molding compound and the first semiconductor die, wherein the IMD structure has a conductive layer electrically coupled to the first RDL structure; and
a second semiconductor package stacked below the first semiconductor package, comprising:
a second RDL structure electrically coupled to the first RDL structure and having a third surface and a fourth surface opposite to the third surface;
a second semiconductor die disposed between the third surface of the second RDL structure and the second surface of the first RDL structure;
a second molding compound disposed between the third surface of the second RDL structure and the second surface of the first RDL structure and surrounding the second semiconductor die;
a plurality of conductive structures disposed on the fourth surface of the second RDL structure and electrically coupled to the second RDL structure; and
an electronic component disposed on the fourth surface of the second RDL structure and electrically coupled to the second RDL structure, wherein the conductive structures and the electronic component are disposed on an external mounting surface of the semiconductor package structure.

38. The semiconductor package structure as defined in claim 37, wherein the electronic component comprises a capacitor, an inductor, a resistor, or a combination thereof.

39. The semiconductor package structure as defined in claim 38, wherein the conductive structures comprise conductive bump structures.

40. The semiconductor package structure as defined in claim 37, wherein the conductive layer comprises an antenna pattern.

41. The semiconductor package structure as defined in claim 37, wherein the conductive layer comprises a conductive shielding layer.

42. The semiconductor package structure as defined in claim 37, wherein the second semiconductor package further comprises a third semiconductor die disposed between the third surface of the second RDL structure and the second surface of the first RDL structure.

43. The semiconductor package structure as defined in claim 37, wherein the first semiconductor package further comprises a plurality of first vias coupled between the conductive layer and the first RDL structure and wherein the second semiconductor structure further comprises a plurality of second vias coupled between the first and second RDL structure.

44. The semiconductor package structure as defined in claim 37, further comprising a passivation layer convering the IMD structure.
